(19) United States
(12) Patent Application Publication
(10) Pub. No.: US 2022/0109748 A1
(43) Pub. Date: Apr. 7, 2022

(54) Mobile Multistation Caddy for Phone

(71) Applicant: Chat Caddie, Inc., Carlsbad, CA (US)

(72) Inventor: Andrew Berlin, Carlsbad, CA (US)

(73) Assignee: Chat Caddie, Inc., Carlsbad, CA (US)

(21) Appl. No.: 17/062,584

(22) Filed: Oct. 3, 2020

(51) Int. Cl. H04M 1/02; G06F 1/16; H05K 5/02

(52) U.S. Cl. CPC H04M 1/026; G06F 1/1632; H05K 5/023; H05K 5/0239; H05K 5/0204

(57) ABSTRACT

Embodiments of the present invention disclose a portable mobile device caddy assembly that permits a user to mount a mobile device to the caddy assembly for a hands free experience with the mobile device. The assembly includes a console member, an attachment member configured to receive a mobile device having a camera, a cup holder having a base member and a sleeve member, and one or more lights that allow a user to illuminate an object for photographic capture by the camera. Additional features include one or more handles for carrying the assembly and electrical ports for connecting the mobile device to an electrical network of the assembly.

### BACKGROUND OF THE INVENTION

### Field of the Invention

The present application relates to mobile device mounts, and particularly to mounts for video capturing devices and work stations.

### Description of Related Art

Thanks to developments in virtual meeting software and hardware, office workers are now able to hold meetings and video calls with greater ease from the comfort of their own homes. As remote working has become more commonplace for businesses, user demand for devices that further aid the convenience of virtual meetings and video calls has increased. In general, users perform virtual meetings or video calls through a computing device having a camera and a microphone that correspondingly captures video image and sound. The captured video and sound of the user are then transmitted by the computing device in near-realtime over a network to a third party and similarly receives captured video and sound of the third party, where then the computing device can display the captured video on a display screen and play the captured sound on a set of speakers, thereby permitting a near-seamless conversation between the user and the third party from remote locations.

In some instances, the computing device is a mobile device such as a mobile phone or tablet computer; however, these devices typically require the user to manually hold up or prop up the mobile device such that an embedded camera on the mobile device continues to face the user for video capture. Holding the mobile device over a prolonged period can cause user discomfort, and propping up the mobile device often leads to an unstable configuration which can potentially lead to the mobile device falling over. Thus, a handsfree device for mounting the mobile device is desired.

While mobile device mounts are well understood in the art, some shortcomings still remain. A common mobile device mount is used in automobiles to allow the user a hands-free experience with the mobile device while driving; however, this mount is designed to permit the user visibility to the screen but not necessarily to position the mobile device such that the user is the view of the camera of the device. Furthermore, these mounts are generally restricted to specific mountable locations within the cabin of the vehicle (e.g., cigarette lighter or 12-volt charging port), and thus not ideal for quick repositioning of the mount to various locations. Another known mounting device can mount and charge a mobile device and features a light to illuminate an area around the user; however, this mounting device is designed for dimly lit casino environments where the mounting device is permanently fixed and not orientable to allow the user to position the camera towards the user, and the light is directed downwards toward the floor and not toward the user, thereby not improving the lighting of the user for video capture by the camera. Furthermore, this mounting device also features a simple cup holder, which is not ideal for stemmed beverage containers, such as wine or martini glasses, as these containers have a base that is not properly constrained by the cup holder.

Thus, it is desired to have a portable mounting device for a mobile device that is easily repositionable by the user to ensure the user is capturable by the camera of the mobile device as well as combining a configurable cup holder that selectively permits a typical canned or stemmed container and a configurable light that allows the light to be directed toward the face of the user to improve video capture of the user by the camera.

### BRIEF SUMMARY OF THE INVENTION

It is an object of the present application to provide a portable mobile device caddy assembly that permits a user to mount a mobile device to the caddy assembly for a hands free experience with the mobile device, to adjust a configurable light such that it illuminates an object for improved visibility for the user or photographic capture by a camera of the mobile device, and to store a canned or stemmed container (i.e., a beverage), thereby allowing the user to simultaneously carry the mobile phone, the beverage, and the light with one hand. The assembly comprising: a console member; an attachment member in communication with the console member, the attachment member configured to receive a mobile device having a camera; a cup holder in communication with the console member, the cup holder having a base member and a sleeve member; and one or more lights in communication with the console member, wherein the one or more lights illuminate an object for photographic capture by the camera. Additional features include one or more handles for carrying the assembly and electrical ports for connecting the mobile device to an electrical network of the assembly.

Ultimately the invention may take many embodiments. In these ways, the present invention overcomes the disadvantages inherent in the prior art.

The more important features have thus been outlined in order that the more detailed description that follows may be better understood and to ensure that the present contribution to the art is appreciated. Additional features will be described hereinafter and will form the subject matter of the claims that follow.

Many objects of the present application will appear from the following description and appended claims, reference being made to the accompanying drawings forming a part of this specification wherein like reference characters designate corresponding parts in the several views.

Before explaining at least one embodiment of the present invention in detail, it is to be understood that the embodiments are not limited in its application to the details of construction and the arrangements of the components set forth in the following description or illustrated in the drawings. The embodiments are capable of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out the various purposes of the present design. It is important, therefore, that the claims be regarded as including such equivalent constructions in so far as they do not depart from the spirit and scope of the present application.

### BRIEF DESCRIPTION OF THE DRAWINGS

The novel features believed characteristic of the application are set forth in the appended claims. However, the application itself, as well as a preferred mode of use, and further objectives and advantages thereof, will best be understood by reference to the following detailed description when read in conjunction with the accompanying drawings, wherein:

FIG. 1 is a front perspective view of a caddy assembly, in accordance with an embodiment of the present application;

FIG. 2 is a back perspective view of the caddy assembly of FIG. 1;

FIG. 3 is a front perspective view of the caddy assembly of FIG. 1 paired with a mobile device and a canned container;

FIG. 4 is the front perspective view of the caddy assembly of FIG. 3 further illustrating bendable features of a cantilever arm coupled to a light;

FIG. 5 is a front perspective view of the caddy assembly of FIG. 1 paired with a mobile device and a stemmed container; and

FIG. 6 is a functional block diagram illustrating an electrical network environment, in accordance with an embodiment of the present invention.

While the embodiments of the present application are susceptible to various modifications and alternative forms, specific embodiments thereof have been shown by way of example in the drawings and are herein described in detail. It should be understood, however, that the description herein of specific embodiments is not intended to limit the application to the particular embodiment disclosed, but on the contrary, the intention is to cover all modifications, equivalents, and alternatives falling within the spirit and scope of the process of the present application as defined by the appended claims.

### DETAILED DESCRIPTION OF THE INVENTION

Illustrative embodiments of the preferred embodiment are described below. In the interest of clarity, not all features of an actual implementation are described in this specification. It will of course be appreciated that in the development of any such actual embodiment, numerous implementation-specific decisions must be made to achieve the developer's specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

In the specification, reference may be made to the spatial relationships between various components and to the spatial orientation of various aspects of components as the devices are depicted in the attached drawings. However, as will be recognized by those skilled in the art after a complete reading of the present application, the devices, members, apparatuses, etc. described herein may be positioned in any desired orientation. Thus, the use of terms to describe a spatial relationship between various components or to describe the spatial orientation of aspects of such components should be understood to describe a relative relationship between the components or a spatial orientation of aspects of such components, respectively, as the embodiments described herein may be oriented in any desired direction.

The system in accordance with the present invention overcome one or more of the above-discussed problems associated with mounting devices for mobile devices. In particular, the system of the present invention is a portable mobile phone caddy assembly (here forth referred to as “caddy assembly) having an attachment member configured to receive a mobile device, an adjustable cup holder configured to selectively receive either a canned container or a stemmed container, and a configurable light for illuminating an object for photographic capture by a camera. As such, the caddy assembly permits a user to mount a mobile device to the caddy assembly for a hands-free experience with the mobile device, to adjust the configurable light such that it illuminates a selectable region for improved visibility for the user or photographic capture by a camera of the mobile device, and to store a canned or stemmed container (i.e., a beverage), thereby allowing the user to simultaneously carry the mobile phone, the beverage, and the light with one hand. Furthermore, the caddy assembly optionally has a handle that aids in the portability of the assembly.

The system will be understood from the accompanying drawings, taken in conjunction with the accompanying description. Several embodiments of the system may be presented herein. It should be understood that various components, parts, and features of the different embodiments may be combined together and/or interchanged with one another, all of which are within the scope of the present application, even though not all variations and particular embodiments are shown in the drawings. It should also be understood that the mixing and matching of features, elements, and/or functions between various embodiments are expressly contemplated herein so that one of ordinary skill in the art would appreciate from this disclosure that the features, elements, and/or functions of one embodiment may be incorporated into another embodiment as appropriate unless otherwise described.

The system of the present application is illustrated in the associated drawings. As used herein, “system” and “assembly” are used interchangeably. It should be noted that the articles “a”, “an”, and “the”, as used in this specification, include plural referents unless the content clearly dictates otherwise. Additional features and functions are illustrated and discussed below.

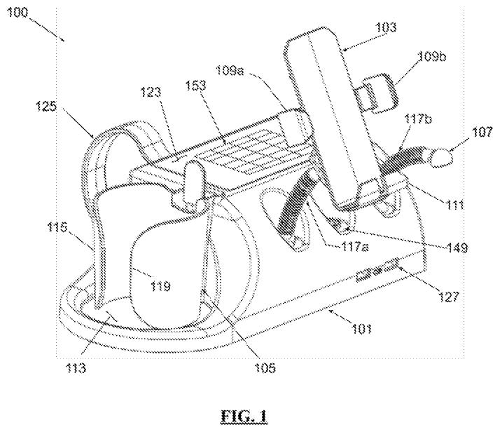

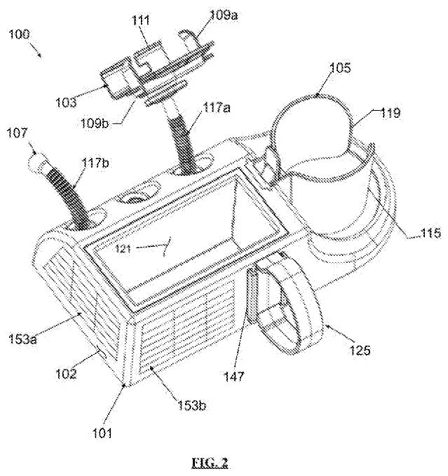

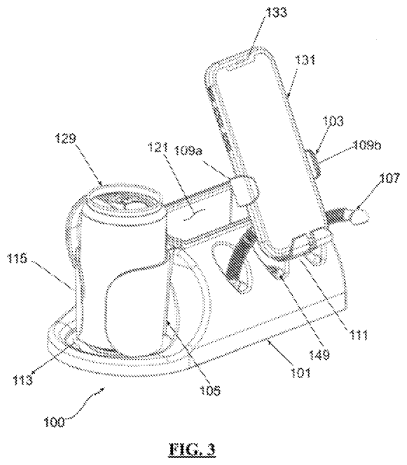

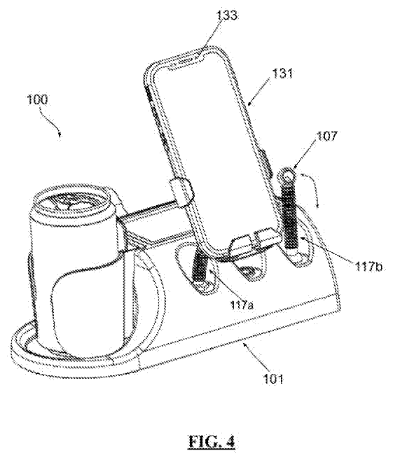

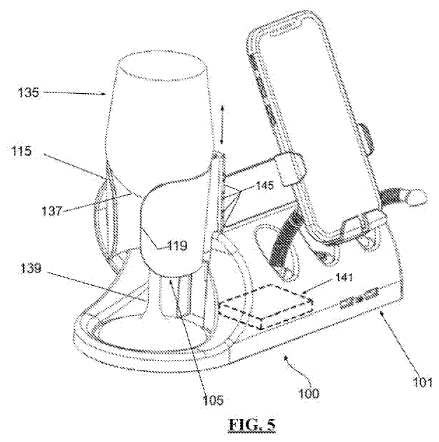

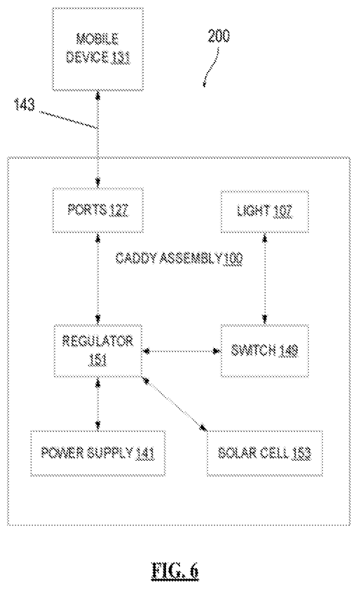

Referring now to the drawings wherein like reference characters identify corresponding or similar elements in form and function through the several views. FIGS. 1-5 illustrate perspective views of a caddy assembly. More specifically, FIGS. 1 and 2 illustrate standalone perspective views of the caddy assembly, FIGS. 3 and 4 illustrate a perspective front view and back view, respectively, of the caddy assembly supporting a mobile device and a canned container, and FIG. 5 illustrates a perspective view of the caddy assembly supporting a mobile device and a stemmed container. Lastly, FIG. 6 illustrates a functional block diagram detailing an electrical network environment of the caddy assembly.

Referring now to FIGS. 1 and 2, wherein FIG. 1 illustrates a front perspective view of caddy assembly 100, and FIG. 2 illustrates a back perspective view of caddy assembly 100, each in accordance with an embodiment of the present invention.

In FIGS. 1 and 2, caddy assembly 100 is a portable mobile device caddy assembly comprising of console member 101, attachment member 103, cup holder 105, and one or more lights (i.e., light 107). In general, console member 101 is a foundational member for uniting the features discussed herein. Console member 101 may be composed out of, but is not limited to, plastic, wood, or metals or any combination thereof known in the art.

In these figures, attachment member 103 is in communication with console member 101, wherein attachment member 103 is configured to receive a mobile device. As used herein, a mobile device is a portable electronic device that has a camera. For example, a mobile device can be a mobile phone, a web camera, a tablet computer, or any other device capable of housing a camera. As such, attachment member 103 is any mounting device known in the art that is configured to receive the previously stated mobile devices. As an exemplary embodiment, as shown in these figures, attachment member 103 is a mobile phone mount having base 111 for supporting a mobile phone and arm members 109a-b for selectively securing the mobile phone against the attachment member 103. In these figures, attachment member 103 is coupled to console member 101 using a cantilever arm (i.e., arm 117a). In general, arm 117a is a bendable structure that permits a user to manipulate arm 117a to a preferred configuration in order to orient attachment member 103 and associated attached mobile device to a preferred direction, yet maintains its configuration when not being manipulated by the user, thus supporting a corresponding weight of attachment member 103 and attached mobile device. For example, arm 117a can be a set of interconnected linkages that are maneuverable by a user into a selected configuration yet maintains the selected configuration via friction between the interconnected linkages after the user has selected the configuration. In another example, arm 117a can be a hose member having a malleable internal support wire that permits the user to bend the hose member and corresponding internal support wire into a selected configuration. Optionally, attachment member 103 may be permanently integrated with console member 101 without arm 117a.

In general, light 107 is a directional light that illuminates an object, such as a face of the user, in order to improve lighting conditions for photographic capture by a camera, such as the camera embedded in the mobile device that is attached to attachment member 103. Light 107 can be any directional light known in the art, such as a LED or incandescent. In general, light 107 is in communication with console member 101. In these figures, light 107 is coupled to console member 101 using a cantilever arm (i.e., arm 117b), wherein arm 117b is of similar form and function as arm 117a in that it permits a user to manipulate arm 117b to a preferred configuration, such as directing light 107 towards a face of the user. An electrical wire connecting between light 107 and a power supply may be run within the body of arm 117b. An electrical network environment for light 107 are further described and detailed with respect to FIG. 6. Optionally, light 107 may be permanently integrated with console member 101 without arm 117b. For example, light 107 may be permanently integrated with console member 101 such that it faces a direction corresponding to an orientation of attachment member 103. In other words, while attachment member 103 holds a mobile device, light 107 is oriented in a same direction as a viewing angle of a camera of the mobile device, such that while a user faces the camera of the mobile device, light 107 simultaneously illuminates a face of the user. While these figures demonstrate an embodiment having a single light, it should be further appreciated that additional lights and corresponding cantilever arms may be incorporated with caddy assembly 100 in order to better improve lighting conditions. Optionally, switch 149 coupled to console member 101 controls electrical operation of light 107.

In general, cup holder 105 is in communication with console member 101. In general, cup holder 105 is a cup holder configured to receive and constrain a beverage container, wherein a beverage container can either be a canned container or a stemmed container. As used herein, a canned beverage is a drink generally known in the art of canned beverages. As used herein, a stemmed container is any container having a bowl and stem, such as a wine glass or a martini glass. In these figures, cup holder 105 comprises base member 113 and sleeve 115, wherein base member 113 generally supports a base of a beverage container, and sleeve 115 has a diameter chosen to constrain the beverage container from falling out of cup holder 105. In these figures, sleeve member 115 is configured to selectively translate with respect to base member 113; as such, various heights selected by a user allows sleeve member 115 to accommodate various container heights. For example, sleeve member 115 can be constrained to translate along a track along console member 101. In these figures, sleeve member 115 has slot 119 that permits a user to pass a stem of a stemmed container through slot 119. Furthermore, sleeve member 115 is configured to support a stemmed container by contact communication with the bowl of the stemmed container. Further features and exemplary uses of cup holder 105 are further illustrated with respect to FIGS. 3 and 5.

Optionally, cup holder 105 is integrally coupled to console member 101. Optionally, only base member 113 is integrally coupled to console member 101, as illustrated in these figures.

Optionally, caddy assembly 100 includes electrical ports 127. In general, electrical ports 127 can be any electrical port known in the art. For example, electrical ports 127 can be USB (Types A, B, C, mini, or micro), Firewire, or a DC charging port. Electrical ports 127 and their network connections are further detailed and described with respect to FIG. 6.

Optionally, caddy assembly 100 includes one or more storage cavities. For example, as illustrated in FIG. 2, console member 101 includes storage cavity 121 that allows a user to place items within storage cavity 121. Optionally, caddy assembly 100 may further include one or more lids that selectively enclose the corresponding one or more storage cavities. In FIG. 1, storage cavity 121 is paired with lid 123 to enclose storage cavity 121 (obscured from view).

Optionally, caddy assembly 100 includes one or more handles that allow a user to carry caddy assembly. In these figures, handle 125 is in communication with console member 101. Optionally, handle 125 is selectively coupled to console member 101 via clip 147 that allows a user to selectively detach handle 125 from console member 101.

Optionally, caddy assembly 100 includes one or more solar cells for charging an embedded power supply. In these figures, solar cells 153a-b are located on surface 102 of console member 101 and solar cell 153c is located on lid 123. Each solar cell and their corresponding location is optional. For example, in one option, caddy assembly 100 only has solar cell 153a; in another option, caddy assembly 100 only has solar cell 153c located on lid 123. Solar cells 153a-c and their network connections are further detailed and described with respect to FIG. 6.

Now referring to FIG. 3, a front perspective view of caddy assembly 100 of FIG. 1 is paired with a mobile device and a canned container.

In this figure, cup holder 105 demonstrates its ability to hold canned container 129 by supporting canned container 129 by contact communication with base member 113 and is further constrained by sleeve member 115.

In this figure, attachment member 103 mounts mobile device 131 having camera 133, wherein mobile device 131 is supported by base 111 and constrained by arms 109a b.

Now referring to FIG. 4, a front perspective view of caddy assembly 100 of FIG. 3 further illustrates bendable features of cantilever arm 117b coupled to light 107. In this figure, light 107 is oriented in the same direction as a field of view of camera 133.

Now referring to FIG. 5, a front perspective view of caddy assembly 100 of FIG. 1 is illustrated as being paired with a mobile device and a stemmed container.

In this figure, stemmed container 135 having bowl 137 and stem 139 is constrained by cup holder 105 by having bowl 137 in contact communication with sleeve member 115. Furthermore, a user is able to pass stem 139 through slot 119 of sleeve 115.

In this figure, power supply 141 is shown with phantom lines as being embedded within console member 101. Power supply 141 is further depicted and described with respect to FIG. 6.

In this figure, sleeve member 115 has index locations 145 that permit sleeve member to selectively couple to console member 101. For example, a user may selectively translate sleeve member 115 to a preferred height, then engage a pin or a biased spring that selectively couples sleeve member 115 to console member 101 based on a location among index locations 145.

Now referring to FIG. 6, a functional block diagram illustrating electrical network environment 200 of caddy assembly 100 is depicted.

In this figure, caddy assembly 100 houses ports 127, light 107, regulator 151, switch 149, power supply 141, and (optionally) solar cell 153 (i.e., solar cells 153a-c or a combination thereof), which are all interconnected over a wired electrical network. In this figure, power supply 141 can be a dry cell battery such as a consumable or rechargeable battery. In this figure, solar cell 153 is capable of providing solar-induced electrical power to the network of caddy assembly 100 via regulator 151. In general, regulator 151 is a voltage regulator generally known in the art that regulates inputted raw voltage to an outputted regulated voltage. Regulator 151 is capable of regulating voltage provided by power supply 141 and/or solar cell 153. Regulator 151 is configured to provide appropriate voltages to light 107 (via switch 149) and ports 127. Switch 149 is any electrical switch known in the art that controls electrical power supplied between regulator 151 and light 107. For example, switch 149 can be a basic single-pole switch or a trimpot switch that allows variable power to light 107.

In this figure, cable 143 connects mobile device 131 to a port among ports 127. In general, cable 143 is an electrical cable that is generally associated with mobile device 131 used for file transfer, charging, or power production and has appropriate corresponding adapters at each end of cable 143 for connecting to mobile device 131 and ports 127 (e.g., USB 2.0 adapter, micro USB adapter, etc.)

In some instances, power supply 141, solar cell 153, or a combination thereof provides power via regulator 151 to light 107 and mobile device 131 (via ports 127). Should power supply 141 run out of power and/or solar cell is unable to provide power, mobile device 131 is capable of providing power to light 107 via ports 127 and regulator 151.

The particular embodiments disclosed above are illustrative only, as the application may be modified and practiced in different but equivalent manners apparent to those skilled in the art having the benefit of the teachings herein. It is therefore evident that the particular embodiments disclosed above may be altered or modified, and all such variations are considered within the scope and spirit of the application. Accordingly, the protection sought herein is as set forth in the description. It is apparent that an application with significant advantages has been described and illustrated. Although the present application is shown in a limited number of forms, it is not limited to just these forms, but is amenable to various changes and modifications without departing from the spirit thereof.

What is claimed is:

1. A portable mobile device caddy assembly, comprising:
a console member;
an attachment member in communication with the console member, the attachment member configured to receive a mobile device having a camera;
a cup holder in communication with the console member, the cup holder having a base member and a sleeve member; and
one or more lights in communication with the console member, wherein the one or more lights illuminate an object for photographic capture by the camera.

2. The assembly of claim 1, wherein the cup holder is integrally coupled to the console member.

3. The assembly of claim 1, wherein the sleeve member is configured to selectively translate with respect to the base member.

4. The assembly of claim 3, wherein the base member of the cup holder is integrally coupled to the console member.

5. The assembly of claim 3, wherein the sleeve member selectively couples to the console member based on one or more index locations.

6. The assembly of claim 1, wherein the cup holder is configured to receive a canned container.

7. The assembly of claim 1, wherein the cup holder is configured to receive a stemmed container having at least a stem and a bowl, wherein the sleeve member is configured to support the stemmed container by contact communication with the bowl.

8. The assembly of claim 7, wherein the sleeve member of the cup holder further comprises a slot for passing the stem of the stemmed container through the sleeve member.

9. The assembly of claim 1, further comprising a cantilever arm coupling the attachment member to the console member.

10. The assembly of claim 9, wherein the cantilever arm is a bendable structure that permits a selectable configuration.

11. The assembly of claim 1, further comprising a cantilever arm that couples the one or more lights to the console member.

12. The assembly of claim 11, wherein the cantilever arm is a bendable structure that permits a selectable configuration.

13. The assembly of claim 1, the console member further comprising one or more storage cavities.

14. The assembly of claim 13, further comprising one or more lids that selectively enclose the corresponding one or more storage cavities.

15. The assembly of claim 1, further comprising one or more handles coupled to the console member.

16. The assembly of claim 15, wherein each of the one or more handles are selectively detachable.

17. The assembly of claim 1, further comprising a power supply stored within the console member.

18. The assembly of claim 17, further comprising one or more electrical ports coupled to the console member, the one or more electrical ports in electrical communication with the power supply.

19. The assembly of claim 17, further comprising the one or more lights in electrical communication with the power supply.

20. A portable mobile device caddy assembly, comprising:
a console member, the console member having one or more storage cavities;
one or more lids that selectively enclose the corresponding one or more storage cavities;
an attachment member in communication with the console member, the attachment member configured to receive an electronic device having a camera;
a cup holder in communication with the console member, the cup holder having a base member and a sleeve member, wherein the sleeve member is configured to selectively translate with respect to the base member, wherein the sleeve member selectively couples to the console member based on one or more index locations, wherein the sleeve member has a slot for passing a stem of a stemmed container through the sleeve member;
a light in communication with the console member, wherein the light illuminates an object for photographic capture by the camera;
a first cantilever arm that couples the attachment member to the console member, wherein the first cantilever arm is a bendable structure that permits a selectable configuration;
a second cantilever arm that couples the light to the console member, wherein the second cantilever arm is a bendable structure that permits a selectable configuration; and
a handle coupled to the console member, wherein the handle is selectively detachable.
